(19) United States
(12) Patent Application Publication
(10) Pub. No.: US 2018/0116052 A1
(43) Pub. Date: Apr. 26, 2018

(54) ELECTRONIC TILE PACKAGING

(71) Applicant: Northrop Grumman Systems Corporation, Falls Church, VA (US)

(72) Inventor: Steven J. Mass, La Palma, CA (US)

(21) Appl. No.: 15/298,313

(22) Filed: Oct. 20, 2016

(51) Int. Cl. H05K 1/14; H05K 1/02; H05K 1/03; H01P 3/08; H01L 25/18; H01L 23/66; H01L 23/498; H01L 23/373

(52) U.S. Cl. CPC H05K 1/144; H01L 2223/6627; H05K 1/0237; H05K 1/0298; H05K 1/0306; H05K 1/0313; H05K 1/0268; H01P 3/08; H01L 25/18; H01L 23/66; H01L 23/49838; H01L 23/49833; H01L 23/49822; H01L 23/3731; H01L 23/3732; H05K 2201/10348; H05K 2201/10378; H05K 2201/1031; H05K 2201/0175; H05K 2201/042; H01L 2223/6644; H05K 1/0204

(57) ABSTRACT

An apparatus includes: electronic tile packaging, the electronic tile packaging comprising: a plurality of tile layers, at least one of the tile layers comprising a crystalline structure having high thermal conductivity.

### SUMMARY

An apparatus includes: electronic tile packaging, the electronic tile packaging comprising: a plurality of tile layers, at least one of the tile layers comprising a crystalline structure having high thermal conductivity.

### DESCRIPTION OF THE DRAWINGS

The accompanying drawings provide visual representations which will be used to more fully describe various representative embodiments and can be used by those skilled in the art to better understand the representative embodiments disclosed herein and their advantages. In these drawings, like reference numerals identify corresponding elements.

FIG. 1 is a drawing of a cross-sectional side view of electronic tile packaging.

FIG. 2 is a drawing of a cross-sectional side view of electronic tile packaging.

FIG. 3 is a drawing of a working embodiment of silicon carbide electronic tile packaging.

FIG. 4 is a drawing of a working embodiment of the filter tile assembly of electronic tile packaging.

FIGS. 5A-5C is a set of drawings of working embodiments of the filter tile assembly for silicon carbide electronic tile packaging.

FIG. 6 is a drawing of a working embodiment of the filter tile assembly for silicon carbide electronic tile packaging.

### DETAILED DESCRIPTION

While the present invention is susceptible of embodiment in many different forms, there is shown in the drawings and will herein be described in detail one or more specific embodiments, with the understanding that the present disclosure is to be considered as exemplary of the principles of the invention and not intended to limit the invention to the specific embodiments shown and described. In the following description and in the several figures of the drawings, like reference numerals are used to describe the same, similar or corresponding parts in the several views of the drawings.

According to embodiments of the invention, electronic tile packaging comprises a plurality of tile layers, at least one of the tile layers comprising a crystalline structure having high thermal conductivity. According to further embodiments of the invention, electronic tile packaging comprises multi-layer, high conductivity crystalline structures. According to yet other embodiments of the invention, at least two of the crystalline structures are connected through an interconnect.

According to embodiments of the invention, at least one tile layer comprises a plurality of structures. According to other embodiments of the invention, at least one of the structures comprises multiple conductor layers. According to still other embodiments of the invention, at least one tile layer comprises one or more of active and passive structures. According to further embodiments of the invention, the structures comprise multiple conductor layers. According to other embodiments of the invention, at least one of the conductor layers is configured for one or more of direct current (DC) routing and command routing. For example, the electronic tile packaging comprises one or more of silicon carbide (SiC), quartz, boron, arsenic, and diamond.

According to embodiments of the invention, active chips are embedded on high performance semiconductor-type structures and electrically bonded together. According to other embodiments of the invention, at least one of the layers comprises a filter.

According to further embodiments of the invention, vertical signal interconnects from one carrier to another are achieved via crystalline interposers. The crystalline structures may be hollowed out or cavitized to make room for chips that sit between each of the layers. Alternatively, or additionally, according to other embodiments of the invention, single layer wafers can be utilized as interposer rings.

According to embodiments of the invention, two or more chips may be bonded together to make multi-layer wafers. According to further embodiments of the invention, at least one of the two or more chips may comprise one or more of an active circuit, a passive circuit, a filter, a switch, and another component.

According to still further embodiments of the invention, a diverse accessible heterogeneous integration (DAHI) chip bonder can be used to assemble multi-level tiles comprising one or more of interposer layers, vertical radio frequency (RF) interconnects, stripline filtering, and monolithic microwave integrated circuits (MMICs).

According to yet other embodiments of the invention, one or more of wafer-level packaging (WLP) and complementary metal-oxide semiconductor (CMOS) can be attached using one or more of DAHI bonding, wafer-level packaging (WLP) bonding, and solder-ball bonding.

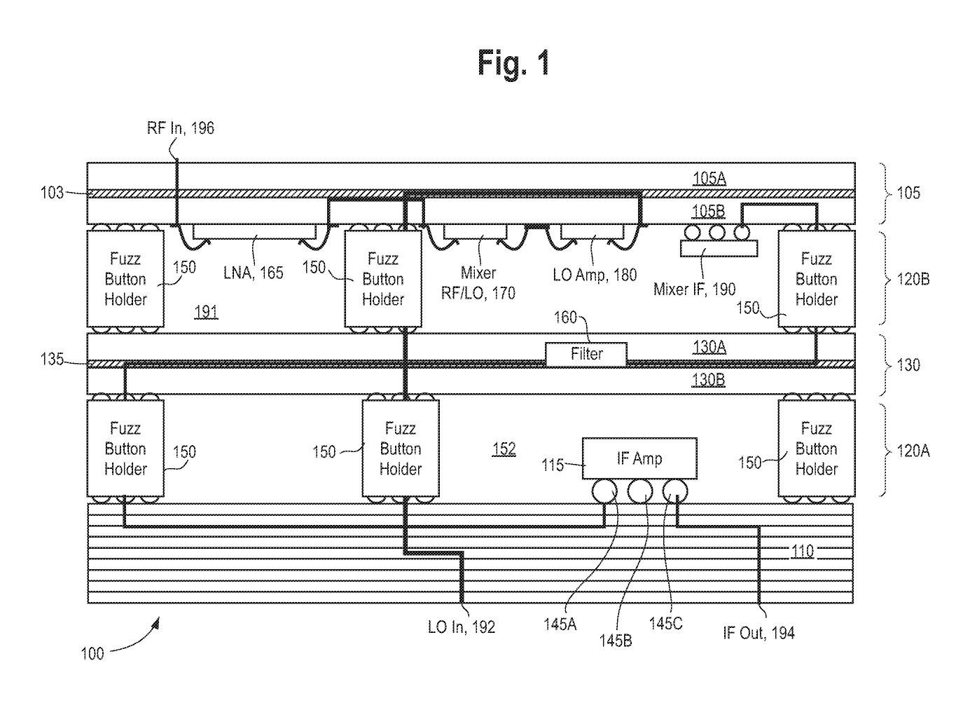

FIG. 1 is a drawing of a cross-sectional side view of electronic tile packaging 100. For example, the electronic tile packaging 100 comprises one or more of silicon carbide (SiC), quartz, boron, arsenic, and diamond. In this embodiment, a conductor 103 is in the middle of two tile layers 105A and 105B. FIG. 1 depicts a true silicon carbide stripline structure.

For example, according to embodiments of the invention, two tile layers of Silicon Carbide are used to create a thick stripline RF layer, with the potential for as many as four more layers for DC routing.

The electronic tile packaging 100 includes an intermediate frequency (IF) printed wiring board (PWB) 110 comprising an intermediate frequency (IF) amplifier 115, a first interposer layer 120A, a second interposer layer 120B, a filter tile assembly 130 comprising a filter tile conductor 135, and the active tile assembly 105 comprising the active conductor layer 103.

The active conductor layer 103 is sandwiched between a dielectric active tile layer 105A on top of it and another dielectric active tile layer 105B beneath it creating a true stripline transmission line structure. Alternative embodiments utilize a microstrip as a conductor in a dielectric material, with a cavity on one side of the microstrip and the dielectric material on the other side. Additional alternative embodiments of the conductor involve coplanar structures in which fields are contained between ground-signal-ground structures. Broadside coupling uses thin tile layers in which the conductor is separated by the dielectric and the fields will couple between the tile layers.

The IF amplifier 115 is bonded to the PWB 110 via one or more interconnects 145A, 145B, and 145C. The first interposer layer 120A makes contact between the PWB 110 and the filter tile assembly 130. The first interposer layer 120A enables signals to transfer between the PWB 110 and the filter tile assembly 130. The first interposer layer 120A also creates a first cavity 152 in which chips such as the IF amplifier 115 can be placed on the PWB 110. The first interposer layer 120A can be used to test the electronic tile packaging 100 prior to final bonding. The first interposer layer 120A can be used as a final electrical contact.

The filter tile assembly 130 typically comprises two or more filter tile layers. As shown in FIG. 1, the filter tile assembly 130 comprises two filter tile layers 130A and 130B. The filter tile assembly 130 further comprises a filter tile conductor 135.

The filter tile conductor 135 is fabricated in a microelectronic foundry setting where sub-micron features can be created. This type of control enables high density, high accuracy features suitable for a signal comprising one or more of a DC signal, a high speed digital signal, and an alternating current (AC) signal. For example, the frequency of the AC signal can range from RF to terahertz.

The tiles can have numerous conductors serving multiple functions. DC conductors can provide power to active circuits such as amplifiers. Control lines can provide configuration states for switches to switch into operation various circuits such as filters, amplification and true time delay phases.

The active tile assembly 105 typically comprises two or more active tile layers. As shown in FIG. 1, the active tile assembly 105 comprises two active tile layers 105A and 105B. The active tile assembly 105 further comprises the active conductor layer 103.

For example, the active conductor layer 103 comprises of any number of signal paths ranging from DC to terahertz frequencies. For example, the active conductor layer 103 comprises a set of RF conductor line lengths 103 configured to create a set of delay lines which can be switched in to create a variable true time delay. Active switch circuits (not shown) may be grown on the tile substrates and used to switch between the desired delay lines.

For example, the spacer 150 comprises an interconnect (not shown). For example, the interconnect comprises one or more of a diverse accessible heterogeneous integration (DAHI) chip bonder, a fuzz button holder, a nanowire, a conductive elastomer, a spring, a crystalline interposer, a metallic interconnect, a solder ball interconnect, and another interconnect. For example, the solder ball interconnect may comprise a gold-tin solder interconnect. For example, the metallic interconnect comprises a direct metal bump interconnect. For example, the metallic interconnect comprises a direct metal bump bonded by thermal compression. For example, the metallic interconnect comprises one or more of a gold-indium interconnect, a gold-gold interconnect, and another direct metal interconnect.

The filter tile assembly comprises a filter 160 operably connected to the IF amplifier 115. The second interposer layer 1206 makes contact between the filter tile assembly 130 and the active tile assembly 105. The second interposer layer 120B enables signals to transfer between the filter tile assembly 130 and the active tile assembly 105. The second interposer layer 120B can be used to test the electronic tile packaging 100 prior to final bonding. The second interposer layer 120B can be used as a final electrical contact.

The active tile assembly may include any number of active and passive circuits. In FIG. 1, the tile 105 includes a low-noise amplifier (LNA) 165, a mixer 170 operably connected to the LNA amplifier 165, and to the LO amplifier 180. For example, a Wilkinson splitter is used to split the LO signal and provide it to multiple mixer circuits within a tile. For example, the IF mixer 170 comprises indium phosphide.

The active tile layer 105 also optionally includes a second mixer 190 operably connected to the filter 160. For example, the second mixer 190 comprises a radio frequency (RF)/local oscillator (LO) mixer 190. For example, the second mixer 190 comprises an intermediate frequency (IF) mixer 190. For example, the IF mixer 190 comprises indium phosphide.

The second interposer layer 120B also creates a second cavity in which chips such as the filter 160 can be placed on the active tile assembly 105. The LNA 165, the first mixer 170, the LO amplifier 180, and the second mixer 190 are bonded to the active tile 105 via one or more interconnects. For example, the spacer 150 comprises an interconnect (not shown).

For example, the interconnect comprises one or more of a diverse accessible heterogeneous integration (DAHI) chip bonder, a fuzz button holder, a nanowire, a conductive elastomer, a spring, a crystalline interposer, a metallic interconnect, a solder ball interconnect, and another interconnect. For example, the solder ball interconnect may comprise a gold-tin solder interconnect. For example, the metallic interconnect comprises a direct metal bump interconnect. For example, the metallic interconnect comprises a direct metal bump bonded by thermal compression. For example, the metallic interconnect comprises one or more of a gold-indium interconnect, a gold-gold interconnect, and another direct metal interconnect.

The LNA 165, the first mixer 170, and the LO amplifier 180 are bonded to the to tile 105 with one or more interconnects. The Mixer IF 190 is shown as bumped and soldered to the tile 105.

An LO input 192 feeds into the LO amplifier 180. An IF output 194 feeds out of the IF amplifier 115. An RF input 196 feeds into the LNA 165.

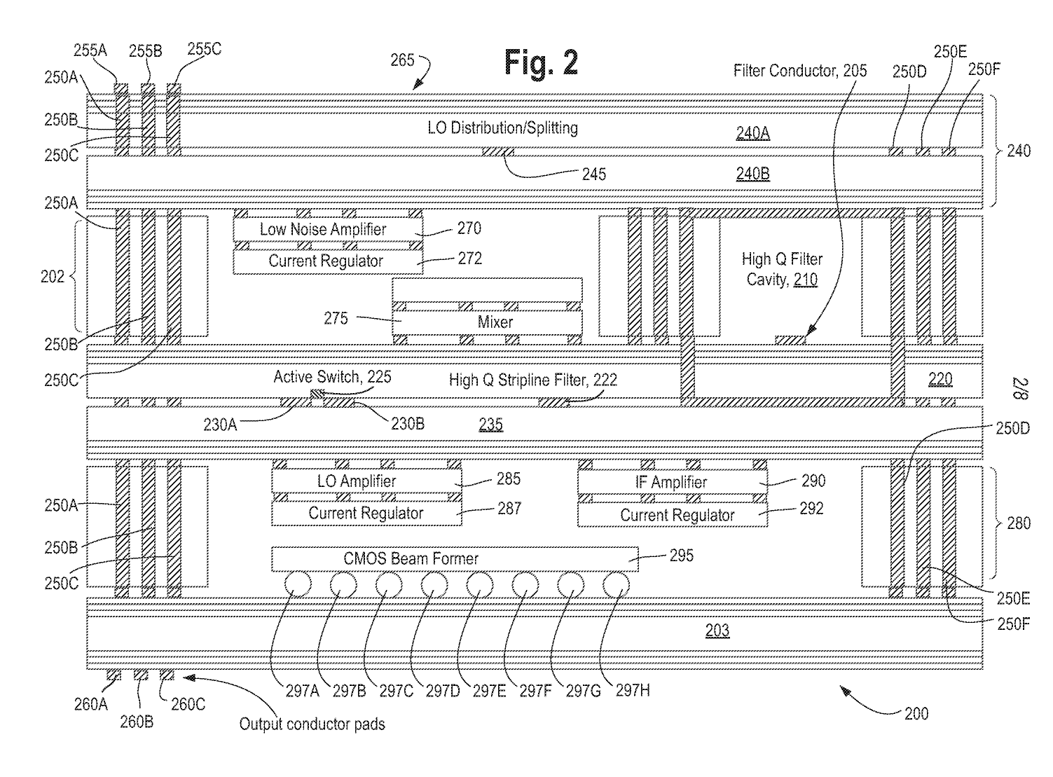

FIG. 2 is a drawing of a cross-sectional side view of electronic tile packaging 200. This example represents an alternative embodiment of the electronic tile packaging comprising an upper interposer ring 202 and a PWB 203. The upper interposer ring 202 in turn comprises a thin, single layer microstrip filter conductor 205. The upper interposer ring 202 further comprises a cavity 210 around the filter conductor 205 that keeps unwanted signals off a signal path of the single layer microstrip filter conductor 205 by creating a Faraday cage. The cavity 210 is configured to shape the signal by controlling the cavity resonances.

For example, the cavity 210 comprises a high quality factor (Q) filter cavity 210 located on top of the single layer microstrip filter conductor 205. For example, Q is at least approximately 100. The RF signal is substantially confined to the high Q filter cavity 210. The high Q filter cavity 210 has substantially no magnetic field disturbance. For example, the high Q filter cavity 210 may be micro-machined.

The electronic tile packaging 200 further comprises a lower filter layer 220. For example, the lower filter layer 220 comprises one of more layers of high purity substrates such as Silicon Carbide, quartz or other board materials. For example, the lower filter layer 220 comprises one or more layers of quartz.

The lower filter layer comprises a stripline filter 222. For example, the stripline filter 222 comprises a high Q stripline filter 222. The lower filter layer 220 comprises an active switch 225. The active switch 225 can be grown as part of a substrate. Alternatively, or additionally, the active switch can be transferred on to the substrate. The electronic tile packaging 200 further comprises one or more delay line conductors 230A and 230B that are sandwiched between the lower filter layer 220 and an active tile layer 235. For example, one or more of the lower filter layer 220 and the active tile layer 235 comprises one or more of 5 mil, 10 mil, and 15 mil Silicon Carbide or quartz. A 15 mil-deep high Q filter cavity 210 has room for wafer-level packaging (WLP) chip integration.

The electronic tile packaging 200 further comprises a tile carrier 240. For example, the tile carrier 240 comprises a crystalline carrier 240. The crystalline carrier 240 comprises a top LO distribution/splitting layer 240A and a bottom LO distribution/splitting layer 240B. The crystalline carrier 240 further comprises an LO conductor 245 sandwiched between the top LO distribution/splitting layer 240A and the bottom LO distribution/splitting layer 240B.

The crystalline carrier 240 can be patterned with thin film 4 (TF4) routing, for example, four tile layers. For example, at least one tile layer comprises one or more of benzocyclobutene (BCB), silicon nitride (SiN), and another tile layer.

Other dielectrics can be used. For example, one or more of a liquid crystal polymer, a teflon, and an oxide can be used. For example, the oxide can comprise silicon oxide. For example, atomic level deposition of Aluminum Oxide can be used.

The electronic tile packaging 200 further comprises conductive vias 250A, 250B, and 250C having respective input conductor pads 255A, 255B, and 255C and having respective output conductor pads 260A, 260B, and 260C. The electronic tile packaging 200 further comprises conductive vias 250D, 250E, and 250F. The crystalline carrier 240 further comprises multiple routing layers 265, the lowest of which is in direct contact with the top LO distribution/splitting layer 240A. The respective input conductor pads 255A, 255B, and 255C contact the top routing layer 265.

For example, one or more of the delay line conductors 230A and 230B comprises an RF conductor and a ring of ground vias (not shown). For example, metallized vias (not shown) are used with diameters of approximately 2 mils.

The upper interposer ring 202 includes signal vias for electrical connections from tile 240 circuits to filter tile 220. The interposer creates cavities for circuits such as LNA 270 and mixer 275.

The electronic tile packaging 200 further comprises a lower interposer ring 280. For example, the lower interposer ring 280 comprises one of more layers of Silicon Carbide, quartz or other board material. For example, the lower interposer ring 280 comprises one or more layers of quartz. For example, the lower interposer ring 280 comprises a Rogers 4003 laminate, sold by Rogers Corporation of Rogers, Connecticut (www.rogerscorp.com).

The electronic tile packaging 200 further comprises circuits mounted on both sides and includes an LO amplifier 285 with stacked current regulator 287, an IF amplifier 290 with stacked current regulator 292, and a a mixer 275. The electronic tile packaging 200 further comprises one of more of active switches, delay lines and filters.

The lower carrier 203 comprises a CMOS beam former 295. The CMOS beam former 295 is bonded to the PWB 203 via one or more interconnects 297A-297H. For example, one or more of the interconnects 297A-297H comprises a known good die interface comprising one or more of solder balls, gold bumps, and copper pillars.

The lower interposer ring 280 can also comprise a second high Q filter cavity (not shown).

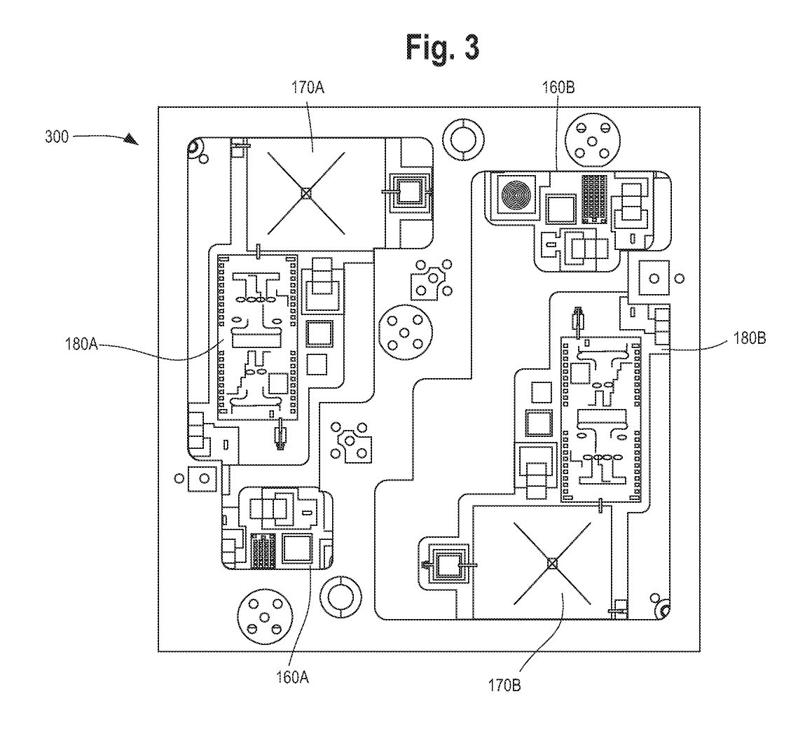

FIG. 3 is a drawing of a working embodiment of silicon carbide electronic tile packaging 300. The picture shows two converter paths in a tile configuration. The local oscillator (LO) amplifier 180A and LNA 160A are operably connected to the Mixer 170A. The local oscillator (LO) amplifier 180B and LNA 160B are operably connected to the mixer 170B.

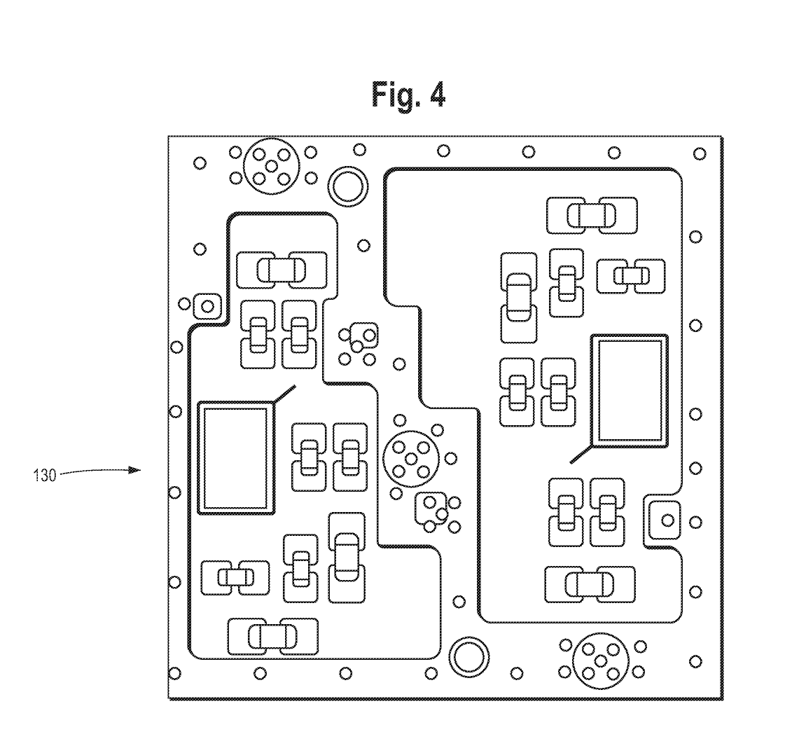

FIG. 4 is a drawing of a working embodiment of the filter tile assembly 130 of electronic tile packaging from FIG. 1.

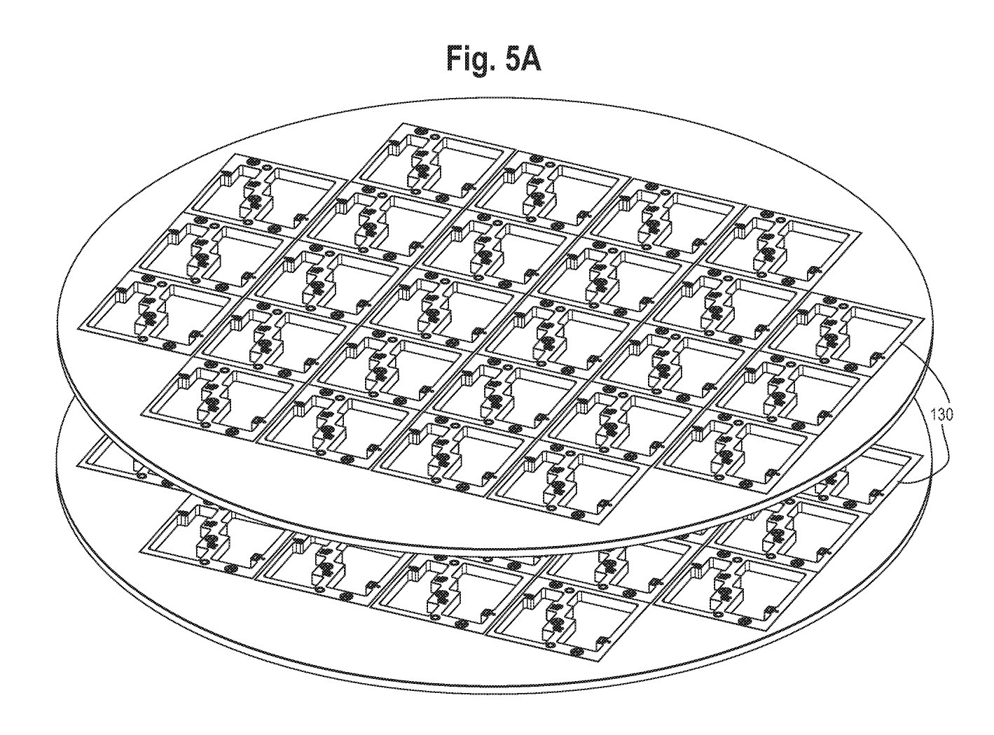

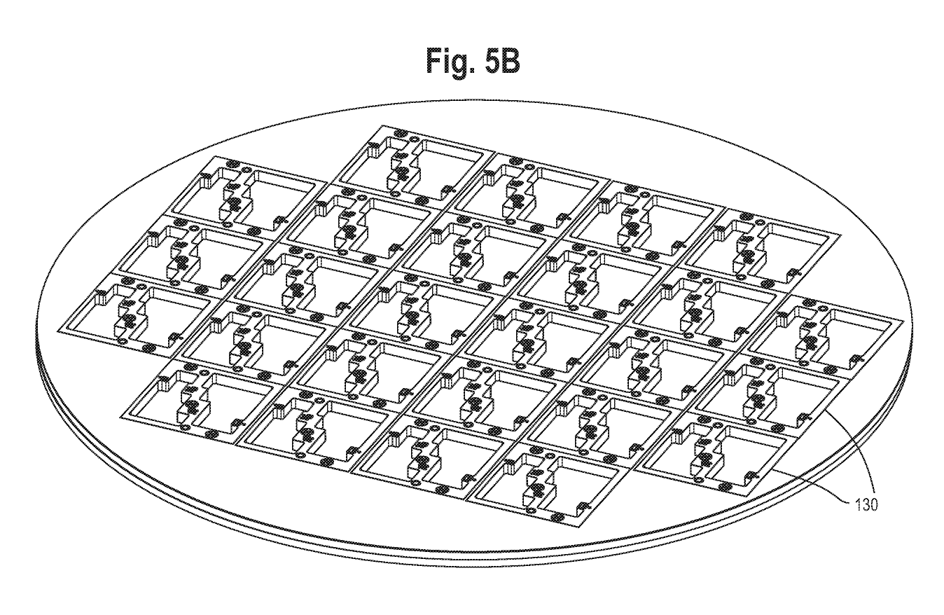

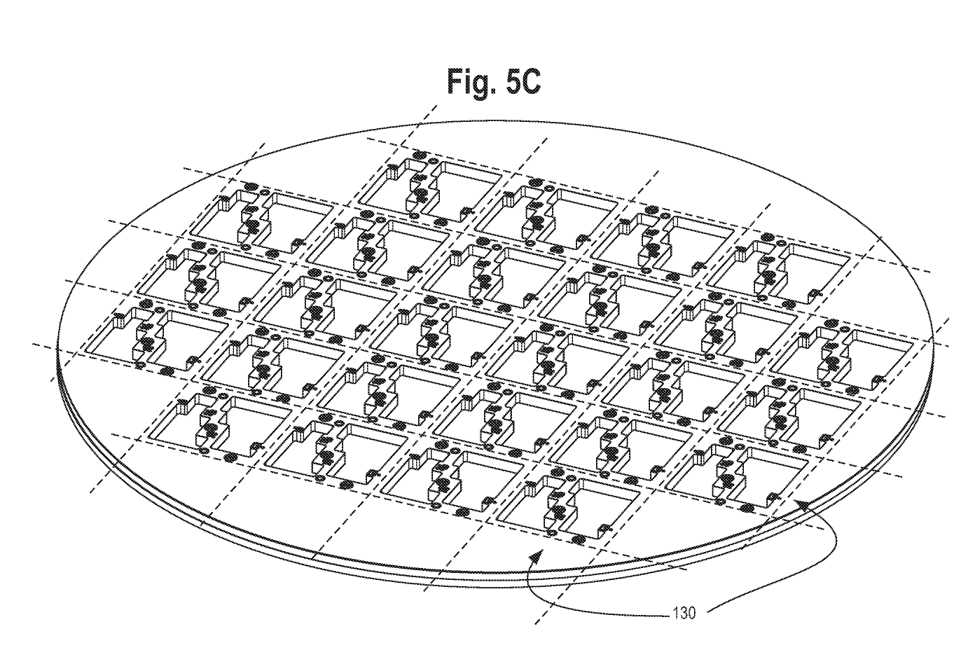

FIGS. 5A-5C is a set of drawings of working embodiments of the filter tile assembly 130 for silicon carbide electronic tile packaging from FIG. 1. They depict the fabrication sequence of etching, bonding and dicing.

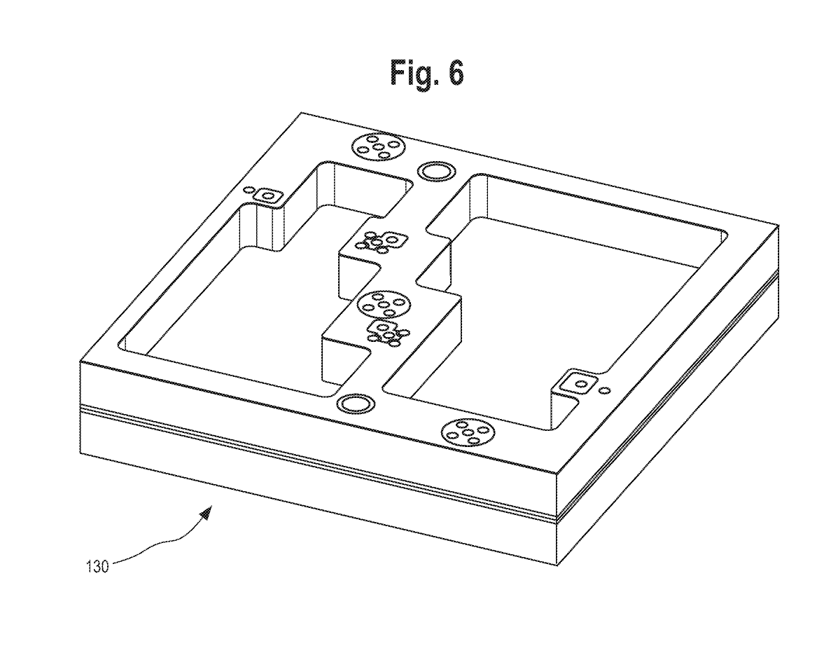

FIG. 6 is a photograph of a working embodiment of the filter tile assembly 130 bonded for silicon carbide electronic tile packaging from FIG. 1.

Advantages conferred by embodiments of the invention include that it permits use of high thermal conductivity materials such as SiC wafers to create a multi-layer circuit with high electrical isolation whose heat generated from the active devices can efficiently flow through the structure to the final heat sink. An additional advantage is that embodiments of the invention enable a combination of ultra-high-density electronic packaging with integration of the highest performance technologies at the lowest cost. Other embodiments of the invention facilitate the creation of multi-layer crystalline structures containing one or more of active high-performance structures and passive high-performance structures that can be stacked into compact vertical assemblies.

A further advantage offered by embodiments of the invention is that the entire electronics of one or more of a phased array and a sub-array can be fully processed in a foundry setting. Another advantage is that embodiments of the invention provide the ability to create an air cavity comprising carved out of sub-cavities.

Additional advantages include that embodiments of the invention provide isolation via size and spacing that can support signal processing architectures operating at higher than approximately 60 gigahertz (GHz). A further advantage is that high conductivity substrates can be used with the invention having conductivity of greater than approximately 300 Watts per (meter-Kelvin) (W/m-K). A still further advantage is that embodiments of the invention permit use of metal to metal interconnects that provide a low thermal impedance for buried active devices within the stack.

A further advantage is that embodiments of the invention permit multiple layers near a surface of the device, permitting additional electrical routing, for example, using one or more of BCB, SiN, and another dielectric materials. For example, a distance of a layer from the surface is less than approximately fifty microns.

Using embodiments of the invention, the entire electronics of one or more of a phased array and a sub-array can be fully processed in a foundry setting. Embodiments of the invention provide feature control of at least approximately 0.1 microns. According to embodiments of the invention, crystalline wafer structures or carriers enable the creation of one or more of ultra-high-performance stripline filters and miniature interconnects. According to further embodiments of the invention, use of SiC enables creation of high thermal performance structures.

According to embodiments of the invention, the apparatus achieves a volume reduction of up to approximately 85%. According to embodiments of the invention, the apparatus achieves an area reduction of up to approximately 75%. Moreover, according to yet further embodiments of the invention, each multi-layer carrier can be tested prior to final stack assembly.

While the above representative embodiments have been described with certain components in exemplary configurations, it will be understood by one of ordinary skill in the art that other representative embodiments can be implemented using different configurations and/or different components. For example, it will be understood by one of ordinary skill in the art that the order of certain fabrication steps and certain components can be altered without substantially impairing the functioning of the invention. For example, the LNA amplifier may be replaced with another type of amplifier without substantially affecting the functioning of the invention. For example, the LO amplifier may be replaced with another type of amplifier without substantially affecting the functioning of the invention.

The representative embodiments and disclosed subject matter, which have been described in detail herein, have been presented by way of example and illustration and not by way of limitation. It will be understood by those skilled in the art that various changes may be made in the form and details of the described embodiments resulting in equivalent embodiments that remain within the scope of the appended claims.

1. An apparatus comprising:
electronic tile packaging, the electronic tile packaging comprising:
a plurality of tile layers, at least one of the tile layers comprising an active crystalline structure having thermal conductivity of at least approximately 300 Watts per (meter-Kelvin), wherein the electronic tile packaging comprises one or more of silicon carbide (SiC), quartz, boron, arsenic, and diamond.

2. (canceled)

3. The apparatus of claim 1, wherein the electronic tile packaging provides isolation configured to support signal processing architectures operating at at least approximately 60 gigahertz (GHz).

4. The apparatus of claim 1, wherein at least two of the crystalline structures are connected through an interconnect.

5. The apparatus of claim 4, wherein the interconnect comprises one or more of a diverse accessible heterogeneous integration (DAHI) chip bonder, a fuzz button holder, a nanowire, a conductive elastomer, a spring, a crystalline interposer, a metallic interconnect, a solder ball interconnect, and another interconnect. For example, the solder ball interconnect may comprise a gold tin solder interconnect.

6. The apparatus of claim 1, wherein at least one of the tile layers comprises a plurality of structures, and wherein at least one of the structures comprises multiple conductor layers.

7. The apparatus of claim 6, wherein at least one of the conductor layers is configured for one or more of direct current (DC) routing and command routing.

8. (canceled)

9. The apparatus of claim 1, further comprising a cavity.

10. The apparatus of claim 9, wherein the cavity has a high quality factor (Q) of at least approximately 100.

11. The apparatus of claim 1, further comprising a tile carrier.

12. The apparatus of claim 11, wherein the tile carrier is patterned with thin film 4 (TF4) routing

13. The apparatus of claim 12, wherein the tile carrier comprises four tile layers.

14. The apparatus of claim 13, wherein at least one of the four tile layers comprises one or more of benzocyclobutene (BCB), silicon nitride (SiN), and another tile layer.

15. The apparatus of claim 1, wherein the electronic tile packaging further comprises an interposer ring.

16. The apparatus of claim 15, wherein the interposer ring comprises one or more layers of silicon carbide, quartz, and another board material.

17. The apparatus of claim 1, wherein the electronic tile packaging further comprises an interposer layer.

18. The apparatus of claim 17, wherein the interposer layer is usable to test the electronic tile packaging.

19. The apparatus of claim 17, wherein the interposer layer is usable as a final electrical contact.

20. The apparatus of claim 1, wherein at least one of the tile layers is positioned less than approximately fifty microns from a surface.

21. The apparatus of claim 1, wherein the electronic tile packaging provides feature control of at least approximately 0.1 microns.

22. The apparatus of claim 1, wherein the electronic tile packaging achieves a volume reduction of up to approximately 85%.

23. The apparatus of claim 1, wherein the electronic tile packaging achieves an area reduction of up to approximately 75%.
